(19) United States
(12) Patent Application Publication
(10) Pub. No.: US 2008/0228417 A1
(43) Pub. Date: Sep. 18, 2008

(54) CHANGING POINT DETECTING CIRCUIT, JITTER MEASURING APPARATUS AND TEST APPARATUS

(75) Inventors: TADAHIKO BABA, Tokyo (JP); Hirokatsu Niijima, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/864,939

(22) Filed: Sep. 29, 2007

Related U.S. Application Data
(63) Continuation of application No. PCT/JP2007/050718, filed on Jan. 18, 2007.

(30) Foreign Application Priority Data
Feb. 10, 2006 (JP) 2006-034521

(51) Int. Cl. G01R 29/26; G06F 19/00

(52) U.S. Cl. 702/69; 702/66; 702/82

(57) ABSTRACT

A changing point detection circuit is provided that detects timing of changing points at which a logic value of a signal under measurement changes and includes a multi-strobe circuit generating a logic value data string obtained by detecting a logic value of the signal under measurement according to a plurality of strobes, each strobe having a different phase; a changing point detecting section detecting in which strobe the logic value changes based on the logic value data string; an edge designation storage section storing in advance information concerning whether an edge-type of the changing point to be detected is a rising edge or a falling edge of the signal under measurement; a selecting section selecting the changing point corresponding to the edge-type stored by the edge designation storage section from among the changing points detected by the changing point detecting section; and a strobe place storage section storing information concerning which strobe the changing point selected by the selecting section corresponds to.

### CROSS REFERENCE TO RELATED APPLICATION

This is a continuation application of PCT/JP2007/050718 filed on Jan. 18, 2007 which claims priority from a Japanese Patent Application NO. 2006-034521 filed on Feb. 10, 2006, the contents of which are incorporated herein by reference.

### BACKGROUND

1. Technical Field

The present invention relates to a changing point detection circuit that detects a changing point of a signal under measurement, a jitter measuring apparatus provided with the changing point detection circuit, and a test apparatus and, more particularly, the present invention relates to a changing point detection circuit that detects a desired changing point of a rising edge or a falling edge.

2. Related Art

As a conventional test of a device under test, such as a semiconductor circuit or the like, a test for judging pass/fail of the device under test based on a signal under measurement output from the device under test is known. For example, a test is known in which jitter of the signal under measurement is calculated and pass/fail of the device under test is judged based on whether the jitter is within a prescribed range.

In such a case, a test apparatus detects an edge (changing point) of the signal under measurement and calculates the jitter based on timing of the edge. For example, the test apparatus generates a plurality of strobes, each having a different phase, in proximity to the edge for every cycle of the signal under measurement. The signal level of the signal under measurement is then detected at the timing of each strobe. A judgment is then made as to whether each signal level is larger than a prescribed threshold value. In addition, a point at which the judgment results switch is detected as the changing point. Through such an operation, the changing point of the signal under measurement can be detected. Furthermore, the jitter of the signal under measurement is calculated based on a phase of the changing point in each cycle of the signal under measurement.

In the conventional measurement method, however, a judgment is not made as to whether the detected changing point is a rising edge or a falling edge. Because of this, there is a case where, for example, the rising edge of the signal under measurement is detected and therefore the falling edge of the signal under measurement is mistakenly detected as the rising edge during the test calculating an amount of jitter of the edge.

In recent years, increasing speed of devices has been accompanied by narrowing of a pulse band of signals under measurement. Because of this, even where a plurality of strobes is generated in proximity to the rising edge to detect the rising edge, there are cases where the falling edge is detected by the strobes. In such a case, two changing points are detected in the same cycle of the signal under measurement.

In the conventional measurement method described above, detecting a desired edge of either the rising edge or the falling edge is problematic. Because of this, for example, an error occurs in the measurement value of the jitter, so that the device under test can not be accurately tested.

### SUMMARY

Therefore, it is an object of an aspect of the present invention to provide a ***Title of the Invention*** that is capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary circuit may include a changing point detection circuit that detects timing of a changing point at which a logic value of a signal under measurement changes. The changing point detection circuit includes a multi-strobe circuit that generates a logic value data string obtained by detecting a logic value of the signal under measurement according to a plurality of strobes, each strobe having a different phase; a changing point detecting section that detects in which strobe the logic value changes based on the logic value data string; an edge designation storage section that stores in advance information concerning whether an edge-type of the changing point to be detected is a rising edge or a falling edge of the signal under measurement; a selecting section that selects the changing point corresponding to the edge-type stored by the edge designation storage section from among the changing points detected by the changing point detecting section; and a strobe place storage section that stores information concerning which strobe the changing point selected by the selecting section corresponds to.

According to a second aspect related to the innovations herein, one exemplary apparatus may include a jitter measuring apparatus that measures jitter of a signal under measurement. The jitter measuring apparatus includes a changing point detection circuit that detects timing of a changing point at which a logic value changes for each signal under measurement input a plurality of times and a jitter calculation section that calculates the jitter of the signal under measurement based on a timing distribution of the changing points detected by the changing point detection circuit. In the jitter measuring apparatus, the changing point detection circuit includes a multi-strobe circuit that generates a logic value data string obtained by detecting a logic value of each signal under measurement according to a plurality of strobes, each strobe having a different phase; a changing point detecting section that detects in which strobe the logic value changes based on the logic value data string; an edge designation storage section that stores in advance information concerning whether the changing point to be detected is a rising edge or a falling edge of the signal under measurement; a selecting section that selects the changing point stored by the edge designation storage section from among the changing points detected by the changing point detecting section; and a strobe place storage section that stores information concerning which strobe the changing point selected by the selecting section corresponds to.

According to a third aspect related to the innovations herein, one exemplary apparatus may include a test apparatus that tests a device under test. The test apparatus includes an input section that inputs a test signal into the device under test, a jitter measuring apparatus that measures jitter of a signal under measurement output by the device under test in response to the test signal, and a judgment section that judges pass/fail of the device under test based on the jitter measured by the jitter measuring apparatus. In the test apparatus, the jitter measuring apparatus includes a changing point detection circuit that detects timing of a changing point at which a logic value changes for each signal under measurement input a plurality of times and a jitter calculation section that calculates the jitter of the signal under measurement based on a timing distribution of the changing points detected by the changing point detection circuit. In the test apparatus, the changing point detection circuit includes a multi-strobe circuit that generates a logic value data string obtained by detecting a logic value of each signal under measurement according to a plurality of strobes, each strobe having a different phase; a changing point detecting section that detects in which strobe the logic value changes based on the logic value data string; an edge designation storage section that stores in advance information concerning whether the changing point to be detected is a rising edge or a falling edge of the signal under measurement; a selecting section that selects the changing point stored by the edge designation storage section from among the changing points detected by the changing point detecting section; and a strobe place storage section that stores information concerning which strobe the changing point selected by the selecting section corresponds to.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows an exemplary configuration of a test apparatus 100 according to an embodiment of the present invention.

FIG. 2 shows an exemplary configuration of a changing point detection circuit 22.

FIG. 3 shows an exemplary configuration of a changing point detecting section 36, a selecting section 38, and a strobe place storage section 42.

FIG. 4 describes an exemplary operation of the changing point detection circuit 22.

FIG. 5 shows an exemplary phase distribution of changing points acquired by the strobe place storage section 42.

FIG. 6 shows another example of a configuration of the changing point detection circuit 22.

FIG. 7 describes an exemplary operation of the changing point detection circuit 22.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

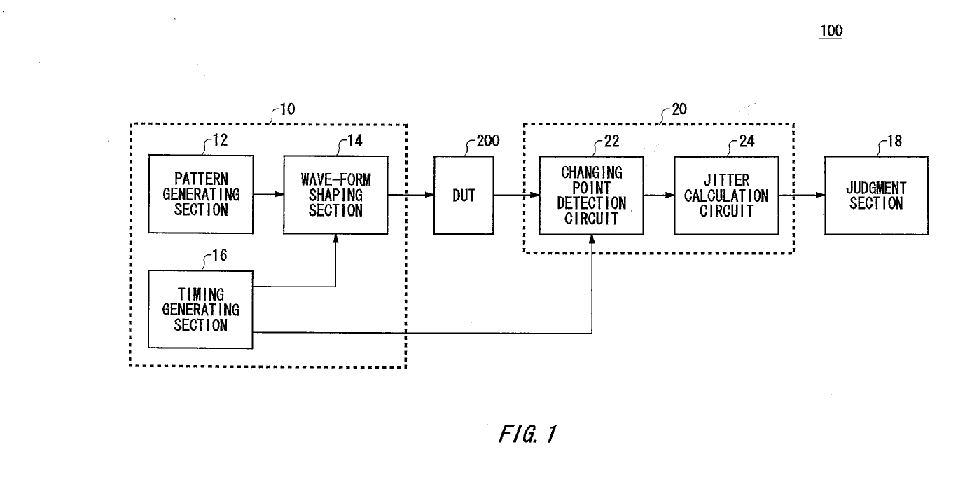

FIG. 1 shows an exemplary configuration of a test apparatus 100 according to an embodiment of the present invention. The test apparatus 100 is an apparatus that tests a device under test 200 and is provided with an input section 10, a jitter measuring apparatus 20, and a judgment section 18.

The input section 10 inputs a test signal into the device under test 200. Here, the test signal is a signal that causes the device under test 200 to output a prescribed output signal, for example. The input section 10 includes a pattern generating section 12, a waveform shaping section 14, and a timing generating section 16.

The pattern generating section 12 generates a test pattern that shows a waveform pattern of the test signal. The waveform shaping section 14 forms the test signal based on the test pattern. For example, the waveform shaping section 14 generates a test signal sequentially showing a voltage level displayed by the test pattern in accordance with a supplied timing clock. The timing generating section 16 generates the timing clock supplied to the waveform shaping section 14.

The jitter measuring apparatus 20 measures jitter of the signal under measurement output by the by the device under test 200 in response to the test signal. The jitter measuring apparatus 20 includes a changing point detection circuit 22 and a jitter calculation section 24.

The changing point detection circuit 22 detects a timing of a changing point, which is a point at which a logic value of the signal under measurement changes. At this time, the input section 10 repeatedly outputs the signal under measurement to the device under test 200 at prescribed test cycles. Furthermore, the changing point detection circuit 22 detects a timing of each changing point of the signal under measurement in each test cycle.

The jitter calculation section 24 detects the jitter of the signal under measurement based on a timing distribution of the changing points detected by the changing point detection circuit 22. For example, the jitter calculation section 24 may calculate a period in the test cycle in which the frequency at which the changing points are detected is greater than or equal to a prescribed value and may calculate the aforementioned period as the amount of jitter of the signal under measurement.

The judgment section 18 makes a judgment concerning pass/fail of the device under test 200 based on the jitter measured by the jitter measuring apparatus 20. For example, the judgment section 18 may make a judgment concerning pass/fail of the device under test 200 based on whether the jitter detected by the jitter measuring apparatus 20 is greater than or equal to a predetermined value.

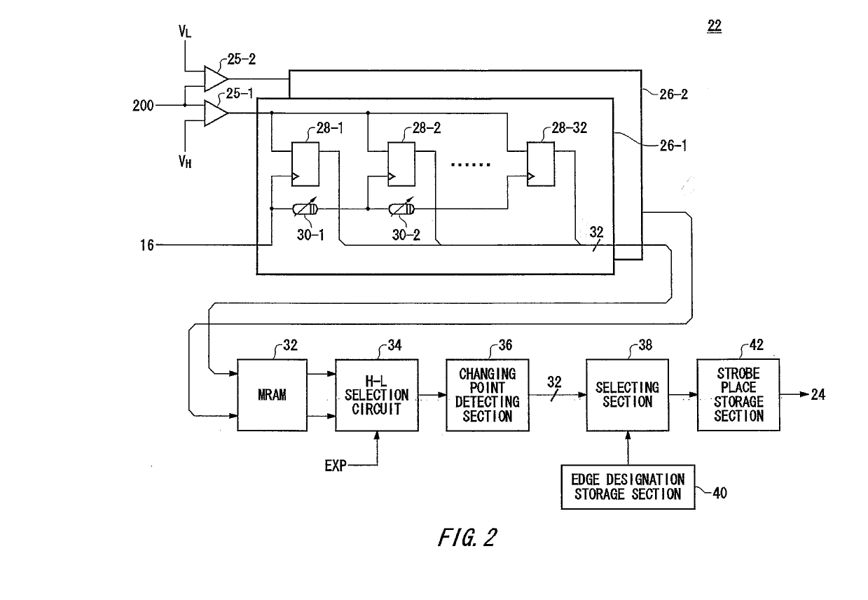

FIG. 2 shows an exemplary configuration of the changing point detection circuit 22. The changing point detection circuit 22 is provided with two level comparison circuits (25-1 and 25-2, hereinafter referred to collectively as 25), two multi-strobe circuits (26-1 and 26-2, hereinafter referred to collectively as 26), a storage device 32, an H-L selection circuit 34, a changing point detecting section 36, a selecting section 38, an edge designation storage section 40, and a strobe place storage section 42.

Each level comparison circuit 25 receives the signal under measurement output by the device under test 200, compares the voltage level of the signal under measurement to a predetermined reference voltage, and outputs a comparison result. For example, the level comparison circuit 25-1 outputs a logic value of one in a case where the voltage level of the signal under measurement is greater than the reference voltage VH and outputs a logic value of zero in a case where the voltage level of the signal under measurement is less than or equal to the reference voltage VH. In other words, the level comparison circuit 25-1 sets the H-level voltage level as the expected value and converts the signal under measurement into a binary signal. Furthermore, the level comparison circuit 25-2 outputs a logic value of zero in a case where the voltage level of the signal under measurement is greater than the reference voltage VL and outputs a logic value of one in a case where the voltage level of the signal under measurement is less than or equal to the reference voltage VL. In other words, the level comparison circuits 25-2 sets the L-level voltage level as the expected value and converts the signal under measurement into a binary signal.

The multi-strobe circuits 26 are disposed to correspond to the level comparison circuits 25. Each multi-strobe circuit 26 generates a data string of the logic values detected according to the plurality of strobes, each having a different phase, based on the logic values of the signal under measurement output by the corresponding level comparison circuit 25.

Each multi-strobe circuit 26 includes a plurality of flip-flops (28-1 to 28-32, hereinafter referred to collectively as 28) and a plurality of delay circuits (30-1 to 30-31, hereinafter referred to collectively as 30). Each flip-flop 28 receives and outputs a logic value of the signal under measurement according to a supplied strobe. The plurality of flip-flops 28 generates a logic value data string obtained by stringing together the output logic values according to the timing of each strobe.

The plurality of delay circuits 30 is disposed corresponding to the plurality of flip-flops 28. Furthermore, the plurality of delay circuits 30 is connected in a cascade arrangement and sequentially delays the clock provided from the timing generating section 16, and each delay circuit 30 generates a strobe. In other words, the plurality of delay circuits 30 generates a plurality of strobes, each strobe having a different phase. Each delay circuit 30 supplies to the corresponding flip-flop 28 the corresponding generated strobe.

Through the configuration described above, the multi-strobe circuit 26 generates the data string of the logic values detected according to the plurality of strobes, each having a different phase, based on the logic values of the signal under measurement. Furthermore, in the present embodiment, the multi-strobe circuit 26 has thirty-two strobe phases, but the number of strobe phases of the multi-strobe circuit 26 is not limited to the description above. The multi-strobe circuit 26 may sample the signal under measurement based on a desired number of strobe phases. Furthermore, a delay amount in each delay circuit 30 may be generally the same.

The storage device 32 stores the logic value data string output by each multi-strobe circuit 26. The storage device 32 may be an MRAM, for example. The H-L selection circuit 34 selects one of the logic value data strings output from the two multi-strobe circuits 26. Which of the logic value data strings is selected by the H-L selection circuit 34 may be controlled by a predetermined H-L selection control signal EXP. Therefore, the desired changing point to be detected can be selected by setting the expected value of the voltage level to be either H-level or L-level in the signal under measurement.

The changing point detecting section 36 detects whether the logic value of the signal under measurement has changed in the logic value data corresponding to one of the strobes based on the logic value data string selected by the H-L selection circuit 34. For example, the changing point detecting section 36 may detect a changing point by calculating an exclusive logical sum of each piece of data, back and forth, in the logic value data string.

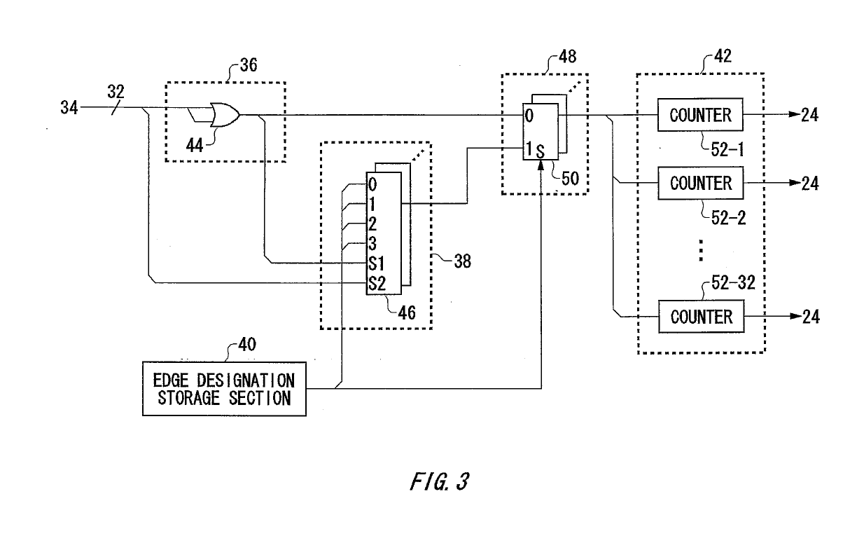

The edge designation storage section 40 stores in advance information concerning whether the edge-type of the changing point to be detected is a rising edge or a falling edge of the signal under measurement. The selecting section 38 selects the changing point corresponding to the edge-type stored by the edge designation storage section 40 from among the changing points detected by the changing point detecting section 36. An example operation of the selecting section 38 is described hereinafter referencing FIG. 3.

The strobe place storage section 42 stores information concerning which strobe the changing point selected by the selecting section 38 corresponds to. Furthermore, the changing point detection circuit 22 executes the operation described above for each signal under measurement in each test period. The strobe place storage section 42 then accumulates information indicating which strobe the changing point corresponds to for each signal under measurement. Therefore, the strobe place storage section 42 stores a phase distribution of the detected changing points for each signal under measurement.

FIG. 3 shows an exemplary configuration of the changing point detecting section 36, the selecting section 38, and the strobe place storage section 42. The changing point detecting section 36 generates a changing point data string, which is obtained by calculating for each piece of data in the logic value data string the exclusive logical sum of data arranged directly after the aforementioned pieces of data. In the present embodiment, the changing point detecting section 36 includes a number of XOR circuits 44 corresponding to the number of strobe phases of the multi-strobe circuit 26.

Each XOR circuit 44 outputs an exclusive logical sum of the logic value data of the signal under measurement detected by the corresponding strobe and the logic value data detected by the strobe directly after the aforementioned strobe. The plurality of XOR circuits 44 outputs the changing point data string obtained by stringing together the exclusive logical values output by each XOR circuit 44 in accordance with the phase of the corresponding strobe. In the changing point data string, data corresponding to a changing point shows a logic value of one and other data shows a logic value of zero.

The selecting section 38 includes a plurality of selection result output circuits 46 corresponding to the plurality of XOR circuits 44. In a case where the corresponding XOR circuit outputs a logic value of one and the data of the corresponding data string indicates a logic value corresponding to the selected edge-type, the selection result output circuit 46 outputs a logic value of one. For example, in a case where the selected edge-type is a rising edge, the selection result output circuit 46 outputs a logic value of one in a case where the corresponding XOR circuit outputs a logic value of one and the data of the corresponding data string indicates a logic value of zero. Furthermore, in a case where the selected edge-type is a falling edge, the selection result output circuit 46 outputs a logic value of one in a case where the corresponding XOR circuit outputs a logic value of one and the data of the corresponding data string indicates a logic value of one.

In the present embodiment, each selection result output circuit 46 includes four input ports 0-3 and data previously set by the edge designation storage section 40 is input into each input port. The edge designation storage section 40 is commonly provided with the plurality of selection result output circuits 46 and inputs identical data into each selection result output circuit 46. Each selection result output circuit 46 outputs the logic value supplied from one of the input ports according to a combination of the logic value output by the corresponding XOR circuit 44 and the logic value of the data of the corresponding logic value data string.

For example, in a case where a rising edge is selected, a logic value of one may be input into the input port 0 and a logic value of zero may be input into the other input ports. In a case where a logic value of one is output from the corresponding XOR circuit 44 and the data of the corresponding logic value data string indicates a logic value of zero, the selection result output circuit 46 outputs the logic value of one input by the input port 0 and, in other cases, the selection result output circuit 46 the outputs the logic value of zero input by the other input terminals 1-3. Therefore, each selection result output circuit 46 outputs a logic value of one in a case where the corresponding XOR circuit 44 detects a rising edge.

The strobe place storage section 42 includes a plurality of counters (52-1 to 52-32, hereinafter referred to collectively as 52) corresponding to the plurality of selection result output circuits 46. Each counter 52 counts a number of logic values of one output by the corresponding selection result output circuit. Therefore, in a case where the signal under measurement is repeatedly input for every test cycle, the phase distribution of the desired edge of the signal under measurement can be acquired.

Furthermore, as shown in FIG. 3, the changing point detection circuit 22 may be provided with a test mode selection circuit 48. The test mode selection circuit 48 switches between detecting changing points while focusing on the desired edge-type of the signal under measurement and detecting changing points while focusing on all edges. The test mode selection circuit 48 includes a plurality of selectors 50 corresponding to the plurality of selection result output circuits 46. Each selector 50 selects and outputs to the strobe place storage section 42 one of either the data output by the corresponding selection result output circuit 46 or the data output by the corresponding XOR circuit 44.

In other words, in a case where the changing points are detected while focusing on the desired edge-type of the signal under measurement, each selector 50 selects the data output by the corresponding selection result output circuit 46. Furthermore, in a case where the changing points are detected while focusing on all edges of the signal under measurement, each selector 50 selects the data output by the corresponding XOR circuit 44. Each counter 52 counts the number of times the logic value of one is output by the corresponding selector 50.

Through the configuration described above, the changing points of the signal under measurement can be detected while focusing on the desired edge-type. In other words, even in a case where a plurality of changing points are detected within a range of the strobe, the changing point of the desired edge-type can be extracted. Therefore, the jitter of the signal under measurement can be accurately calculated and the device under test 200 can be accurately tested.

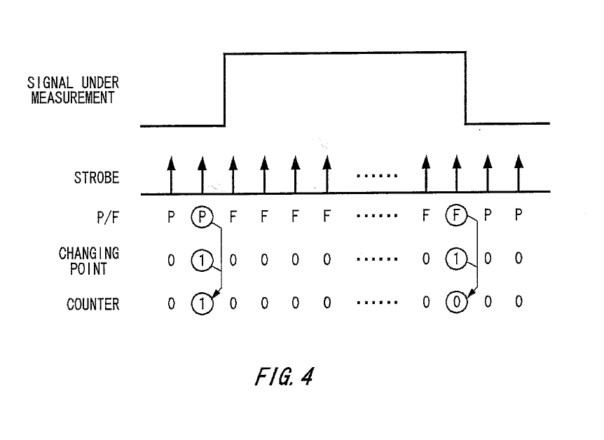

FIG. 4 describes an exemplary operation of the changing point detection circuit 22. As described above, the multi-strobe circuits 26 output strobes, each having a different phase, to the waveform of the signal under measurement. The multi-strobe circuits 26 then output P/F of the logic value data string, which is the detected logic values of the signal under measurement according to each of the strobe signals. In FIG. 4, a logic value of zero is indicated by “P” and a logic value of one is indicated by “F”.

The changing point detecting section 36 outputs a changing point data string, which is obtained by calculating for each piece of data in the logic value data string the exclusive logical sum of data arranged directly after the aforementioned pieces of data. Furthermore, in other examples, the changing point detecting section 36 may calculate for each piece of data in the logic value data string the exclusive logical sum of data arranged directly before the aforementioned pieces of data. In both cases, identical changing point data strings can be acquired.

The selecting section 38 selects from among the pieces of data indicating a logic value of one in the changing point data string the pieces of data indicating that the corresponding data of the logic value data string corresponds to the desired edge-type. For example, in a case where a rising edge is detected, data of the changing point data string in which the data of the corresponding logic value string indicates “P” (a logic value of zero) is extracted, and all other data is converted to a logic value of zero. Such a process can easily be realized by the selection result output circuit 46 described in FIG. 3.

The counter 52 counts the number of times each corresponding piece of data indicates a logic value of one from among the data strings output by the selecting section 38. Therefore, a place distribution of changing points of the desired edge-type can be acquired.

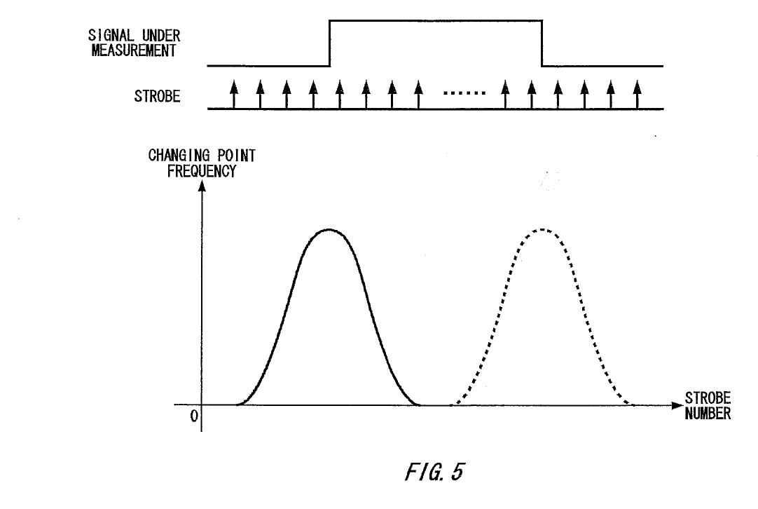

FIG. 5 shows an exemplary phase distribution of changing points acquired by the strobe place storage section 42. In the present embodiment, an example is shown in which changing points of a rising edge of the signal under measurement are detected. As shown in FIG. 5, in a case where a rising edge and a falling edge of the signal under measurement are both included in a strobe range, both edges are detected, so that a measurement focusing on the desired edge can not be performed.

To solve the aforementioned problem, in the present embodiment, the changing point detection circuit 22 can detect the desired edge and eliminate the measurement result of other edges. Therefore, as shown by the solid line of FIG. 5, a phase distribution of changing points with focus placed on the desired edge can be acquired.

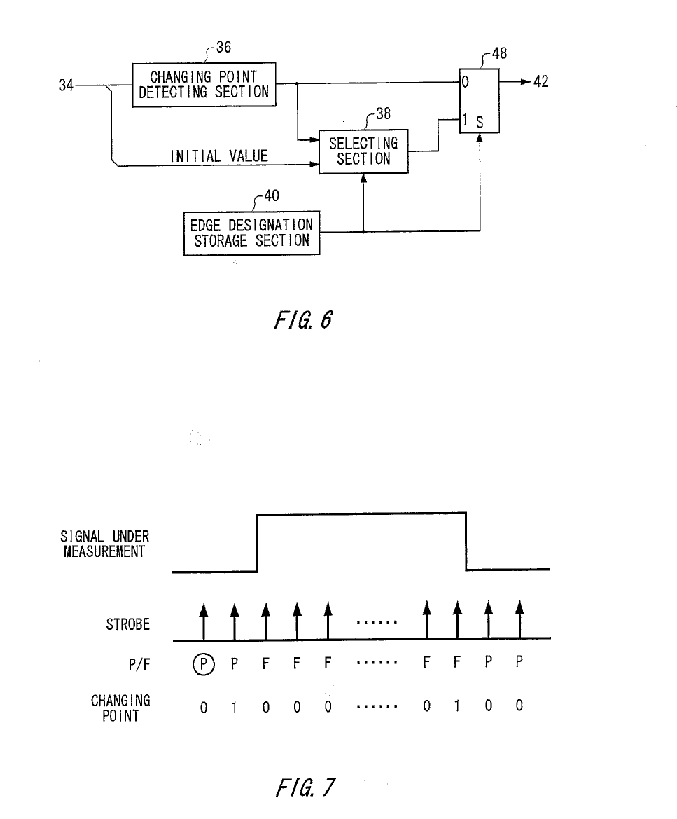

FIG. 6 shows another example of a configuration of the changing point detection circuit 22. In the present embodiment, the configuration from the level comparison circuit 25 to the H-L selection circuit 34 is identical to the configuration of the changing point detection circuit 22 described in FIG. 2, and therefore a description thereof is omitted. The changing point detection circuit 22 according to the present embodiment is provided with the changing point detecting section 36, the selecting section 38, the edge designation storage section 40, and the test mode selection circuit 48.

The changing point detecting section 36, the test mode selection circuit 48, and the edge designation storage section 40 have the same function as the changing point detecting section 36, the test mode selection circuit 48, and the edge designation storage section 40 described in FIG. 2. The selecting section 38 selects a changing point to be detected based on an initial data value of the logic value data string output by the H-L selection circuit 34 and the edge-type stored by the edge designation storage section. Here, the initial data value is the logic value of the first piece of data in the logic value data string, for example.

For example, in a case where a changing point of a rising edge is measured and the logic value of the initial data of the logic value data string is zero, the selecting section 38 outputs a logic value of one for the first logic value of one and outputs a logic value of zero for subsequent logic values of one from among the changing point data strings output by the changing point detecting section 36. Furthermore, in a case where a changing point of a rising edge is measured and the logic value of the initial data of the logic value data string is one, the selecting section 38 outputs a logic value of zero for the second logic value of one and outputs a logic value of zero for subsequent logic values of one from among the changing point data strings output by the changing point detecting section 36.

in a case where a changing point of a falling edge is measured and the logic value of the initial data of the logic value data string is zero, the selecting section 38 outputs a logic value of zero for the second logic value of one and outputs a logic value of zero for subsequent logic values of one from among the changing point data strings output by the changing point detecting section 36. Furthermore, in a case where a changing point of a falling edge is measured and the logic value of the initial data of the logic value data string is one, the selecting section 38 outputs a logic value of one for the first logic value of one and outputs a logic value of zero for subsequent logic values of one from among the changing point data strings output by the changing point detecting section 36.

FIG. 7 describes an exemplary operation of the changing point detection circuit 22. As described above, the multi-strobe circuit 26 outputs a plurality of strobes, each strobe having a different phase, to the waveform of the signal under measurement. The multi-strobe circuit 26 then outputs P/F of the logic value data string obtained by detecting the logic values of the signal under measurement according to each strobe. In FIG. 7, a logic value of zero is indicated by “P” and a logic value of one is indicated by “F”.

The changing point detecting section 36 outputs a changing point data string, obtained by calculating for each piece of data in the logic value data string the exclusive logical sum of data arranged directly after the aforementioned pieces of data. Furthermore, in other examples, the changing point detecting section 36 may calculate for each piece of data in the logic value data string the exclusive logical sum of data arranged directly before the aforementioned pieces of data. In both cases, identical changing point data strings can be acquired.

As described above, the selecting section 38 extracts changing points corresponding to the desired edge-type based on the logic value of the initial data of the logic value data string. For example, in a case where a rising edge is detected and, as shown in FIG. 7, the logic value of the initial data is “P”, the selecting section 38 extracts the first changing point of the changing point data string. Through such an operation, a phase distribution of changing points of the desired edge can be acquired.

While the embodiment of the present invention has been described, the technical scope of the invention is not limited to the above described embodiment. It is apparent to persons skilled in the art that various alternations and improvements can be added to the above-described embodiment. It is also apparent from the scope of the claims that the embodiments added with such alterations or improvements can be included in the technical scope of the invention.

As made clear by the above, through an embodiment of the present invention, a phase distribution of changing points of the desired edge can be acquired. Therefore, jitter of the signal under measurement can accurately be measured. Furthermore, a device under measurement can accurately be tested.

What is claimed is:

1. A changing point detection circuit that detects timing of a changing point at which a logic value of a signal under measurement changes, comprising:
a multi-strobe circuit that generates a logic value data string obtained by detecting a logic value of the signal under measurement according to a plurality of strobes, each strobe having a different phase;
a changing point detecting section that detects in which strobe the logic value changes based on the logic value data string;
an edge designation storage section that stores in advance information concerning whether an edge-type of the changing point to be detected is a rising edge or a falling edge of the signal under measurement;
a selecting section that selects the changing point corresponding to the edge-type stored by the edge designation storage section from among the changing points detected by the changing point detecting section; and
a strobe place storage section that stores information concerning which strobe the changing point selected by the selecting section corresponds to.

2. The changing point detection circuit according to claim 1, wherein:
the changing point detecting section generates a changing point data string, which is obtained by calculating for each piece of data in the logic value data string an exclusive logical sum of data arranged directly after said pieces of data;
the selecting section selects from among data indicating a logic value of one in the changing point data string data indicating that corresponding data of the logic value data string has a logic value corresponding to the selected edge-type; and
the strobe place storage section stores information concerning which strobe the data selected by the selecting section corresponds to.

3. The changing point detection circuit according to claim 2, wherein:
the changing point detecting section includes a plurality of XOR circuits corresponding to the plurality of strobes in the multi-strobe circuit;
each XOR circuit outputs an exclusive logical sum of the logic value of the signal under measurement detected by the corresponding strobe and the logic value detected by a strobe directly after said strobe;
the selecting section includes a plurality of selection result output circuits corresponding to the plurality of XOR circuits; and
each selection result output circuit outputs a logic value of one in a case where the corresponding XOR circuit outputs a logic value of one and the data of the corresponding logic value data string indicates a logic value corresponding to the selected edge-type.

4. The changing point detection circuit according to claim 3, wherein:
the multi-strobe circuit receives the signal under measurement a plurality of times and generates the logic value data string a plurality of times according to each signal under measurement;
the strobe place storage section includes a plurality of counters corresponding to the plurality of selection result output circuits; and
each counter counts a number of times a logic value of one is output by the corresponding selection result output circuit.

5. The changing point detection circuit according to claim 4, wherein:
each selection result output circuit includes four input ports, each supplied with a logic value, and outputs a logic value supplied to one of the input ports according to a combination of the logic value output by the corresponding XOR circuit and the logic value of the data of the corresponding logic value data string; and
the changing point detecting section further includes an edge designation storage section 40 that inputs a logic value of one into the selected input port and inputs a logic value of zero into the other input ports in a case where the XOR circuit outputs a logic value of one and the data of the logic value data string indicates a logic value corresponding to the selected edge.

6. The changing point detection circuit according to claim 5, wherein the edge designation storage section is commonly provided to the plurality of selection result output circuits.

7. The changing point detection circuit according to claim 1, wherein the selecting section selects the changing point based on an initial data value of the logic value data string and the edge-type stored by the edge designation storage section.

8. A jitter measuring apparatus that measures jitter of a signal under measurement, comprising a changing point detection circuit that detects timing of a changing point at which a logic value changes for each signal under measurement input a plurality of times and a jitter calculation section that calculates the jitter of the signal under measurement based on a timing distribution of the changing points detected by the changing point detection circuit, wherein the changing point detection circuit includes:
a multi-strobe circuit that generates a logic value data string obtained by detecting a logic value of each signal under measurement according to a plurality of strobes, each strobe having a different phase;
a changing point detecting section that detects in which strobe the logic value changes based on the logic value data string;
an edge designation storage section that stores in advance information concerning whether the changing point to be detected is a rising edge or a falling edge of the signal under measurement;
a selecting section that selects the changing point stored by the edge designation storage section from among the changing points detected by the changing point detecting section; and
a strobe place storage section that stores information concerning which strobe the changing point selected by the selecting section corresponds to.

9. A test apparatus that tests a device under test, comprising:
an input section that inputs a test signal into the device under test;
a jitter measuring apparatus that measures jitter of a signal under measurement output by the device under test in response to the test signal; and
a judgment section that judges pass/fail of the device under test based on the jitter measured by the jitter measuring apparatus, and wherein:
the jitter measuring apparatus includes:
a changing point detection circuit that detects timing of a changing point at which a logic value changes for each signal under measurement input a plurality of times; and
a jitter calculation section that calculates the jitter of the signal under measurement based on a timing distribution of the changing points detected by the changing point detection circuit; and
the changing point detection circuit includes:
a multi-strobe circuit that generates a logic value data string obtained by detecting a logic value of each signal under measurement according to a plurality of strobes, each strobe having a different phase;
a changing point detecting section that detects in which strobe the logic value changes based on the logic value data string;
an edge designation storage section that stores in advance information concerning whether the changing point to be detected is a rising edge or a falling edge of the signal under measurement;
a selecting section that selects the changing point stored by the edge designation storage section from among the changing points detected by the changing point detecting section; and
a strobe place storage section that stores information concerning which strobe the changing point selected by the selecting section corresponds to.
